(19) United States
(12) Patent Application Publication
(10) Pub. No.: US 2011/0223747 A1
(43) Pub. Date: Sep. 15, 2011

(54) METHOD FOR PRODUCING POLYCRYSTALLINE LAYERS

(75) Inventors: Michael Scholz, Kottgeisering (DE); Robert Lechner, Munchen (DE); Martin Stutzmann, Erding (DE)

(73) Assignee: Dritte Patentportfolio Beteiligungsgesellschaft mbH & Co. Kg, Schoenefeld/Waltersdorf (DE)

(21) Appl. No.: 12/997,077

(22) PCT Filed: Jun. 9, 2009
(86) PCT No.: PCT/EP2009/057122

§ 371 Date: Jun. 2, 2011

(30) Foreign Application Priority Data
Jun. 9, 2008 (EP) 08157885.8

(51) Int. Cl. H01L 21/20

(52) U.S. Cl. 438/482; 257/E21.09

(57) ABSTRACT

In a method for producing polycrystalline layers a sequence of layers is deposited on a substrate (1), the sequence of layers comprising an amorphous initial layer (4), a metallic activation layer (2) and an intermediate layer (3) disposed between the amorphous initial layer (4) and the activation layer (2). The intermediate layer (3) is produced on the basis of titanium. The sequence of layer is heat treated for producing a polycrystalline final layer at the location of the activation layer (2).

The invention relates to a method for producing polycrystalline layers comprising:
depositing a sequence of layers on a substrate, the sequence of layers comprising an amorphous initial layer, a metallic activation layer and an intermediate layer disposed between the amorphous initial layer and the activation layer; and
performing a heat treatment for producing a polycrystalline final layer at the location of the activation layer.

Such a method is known from SCHNEIDER, Jens: Nucleation and growth during the formation of polycrystalline silicon thin films, Dissertation, TU Berlin, 2005. According to the known method, an intermediate layer made from molybdenum is used for a metal induced crystallization (=MIC) process. In this process, an aluminum layer is deposited on a substrate and covered by a molybdenum layer. After the deposition of the molybdenum layer on the aluminum layer an amorphous silicon layer is formed above the molybdenum layer. The sequence of layers is subjected to a heat treatment. During the heat treatment silicon atoms from the amorphous silicon layer diffuse into the aluminum layer. If the saturation limit is reached crystalline silicon seeds are formed in the activation layer along the intermediate layer, which acts as a diffusion barrier. This diffusion barrier must be thermally stable. In particular, the melting point of the intermediate layer should be much higher than the process temperature during the heat treatment. This condition can be fulfilled by molybdenum since the melting temperature of molybdenum is much higher than the general process temperature. A further requirement is the chemical stability of the intermediate layer. However, the intermediate layer made from molybdenum turned out to be unstable in some experiments since molybdenum reacted both with aluminum and silicon.

Usually, metal induced crystallization processes use an oxide layer as intermediate layer. GJUKIC, M.; BUSCHBECK, M.; LECHNER, R.; STUTZMANN, M.; Appl. Phys. Lett. 85, 2134, 2004 discloses an aluminum induced layer exchange (=ALILE) in which a polycrystalline semiconductor material is formed from an amorphous semiconductor material deposited on an aluminum layer whose surface has been oxidized prior to the deposition of the amorphous semiconductor layer.

The production of crystalline thin layers of semiconductor materials on cheap substrates, as for instance glass, is very important for spatially extended electronic circuit elements, in particular, solar cells and monitors that are produced based on the so called thin film transistor (=TFT) technology. The functionality of these circuit elements is determined by the electric properties of the semiconducting material. These properties depend strongly on the microscopic structure. In this context, amorphous, nanocrystalline, microcrystalline, polycrystalline and monocrystalline materials are distinguished. With increasing crystallinity from amorphous materials to monocrystalline materials the electrical properties are improving. For example, the switching times of amorphous TFT-monitors are longer than the switching times of microcrystalline TFT-monitors, and the efficiency of amorphous solar cells is lower than the efficiency of poly-crystalline solar cells.

If the aluminum induced layer exchange shall result in a coarse grained polycrystalline layer with a grain size greater than 20 μm, a low process temperature typically below 500° C. is required. This results into very slow processes that may last for several hours.

GJUKIC, M., “Metal induced crystallization of silicon-germanium alloys”, in: Selected topics of semiconductor physics and technology, no. 86, 2007 discloses a silver-induced layer exchange (AgILE) process whose reliability under industrial conditions is problematic. A process with an inverted sequence of layers with the amorphous initial layer on the substrate and an outer metallic activation layer seems to be infeasible so far. However, such a process with an inverted sequence of layer would be advantageous for the production of solar cells, since a highly reflecting silver conduct on the backside of the polycrystalline semiconductor layer would be obtained by such a process.

Proceeding from this related art, the present invention seeks to provide a fast and reliable method for producing polycrystalline thin films.

This object is achieved by a method having the features of the independent claim. Advantageous embodiments and refinements are specified in claims dependent thereon.

In the method, the intermediate layer is produced on the basis of titanium. An intermediate layer made from titanium turned out to be a chemical and thermally stable diffusion barrier for a metal induced crystallization process. In particular, high quality polycrystalline layers were obtained within a comparatively short process time period.

The results of the crystallization process were even better if the intermediate layer based on titanium were oxidized for creating an additional layer of titanium oxide.

It was further demonstrated that the intermediate layer may have a thickness between 1 nm to 10 nm. Therefore, a relatively thin intermediate layer is sufficient for stabilizing the crystallization process.

The amorphous initial layer generally comprises at least one semiconductor material such as silicon or germanium. These materials are interesting candidates for spatially extended circuit elements such as solar cells and thin film displays.

The activation layer is generally produced on the basis of a metal, for instance aluminum, on the basis of a transition metal such as silver, or on the basis of a metalloid such as antimony.

The activation layer may have a thickness between 10 nm and 600 nm, preferably between 100 nm and 300 nm. In most cases the metallic activation layer will have a thickness, which is smaller than the thickness of the amorphous initial layer. Thus, nearly the complete amorphous initial layer can be transformed into a closed polycrystalline material film.

The process temperature of the heat treatment process is advantageously kept below the eutectical temperature of material systems formed by the components of the amorphous initial layer and the activation layer, so that no liquid phase occurs during the heat treatment.

Since the process time period, that the process takes for completion, depends on the activation energy of the process, the duration of the heat treatment must be long enough for obtaining a significant coverage. For a coverage of 99.5% of the area of the initial sequence of layers, the process time should be longer than:

t[h]=(Δx[nm]/100 nm)*exp((2*10⁺⁴/T[K])−34.5),

wherein Δx is the thickness of the activation layer measured in nm and T is the process temperature of the heat treatment measured in Kelvin.

In one particular embodiment, the activation layer is deposited on the substrate, the intermediate layer is formed on the activation layer and the amorphous initial layer is deposited on the intermediate layer. Such a method results in a polycrystalline layer formed directly on the substrate.

In a further embodiment, the amorphous initial layer is deposited on the substrate and the intermediate layer is formed on the amorphous initial layer. Finally, the activation layer is deposited on the intermediate layer. This process results in a metallic final layer disposed between the polycrystalline layer and the substrate. Such an arrangement is particularly suited for products that convert radiation into electrical energy since the metallic final layer can act as a reflector and can further be used as electrical contact.

Further advantages and properties of the present invention are disclosed in the following description, in which exemplary embodiments of the present invention are explained in detail based on the drawings:

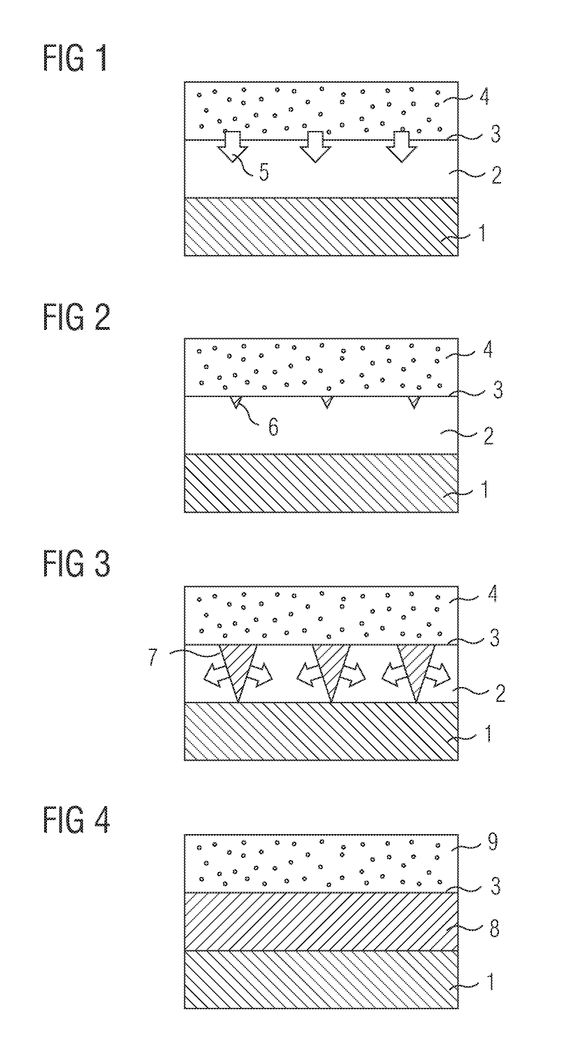

FIGS. 1 to 4 illustrate a metal induced crystallization process with a metallic activation layer disposed on a substrate and an outer amorphous initial layer;

FIGS. 5 to 8 illustrate an inverted metal induced crystallization process with an amorphous initial layer deposited on a substrate and an outer metallic activation layer;

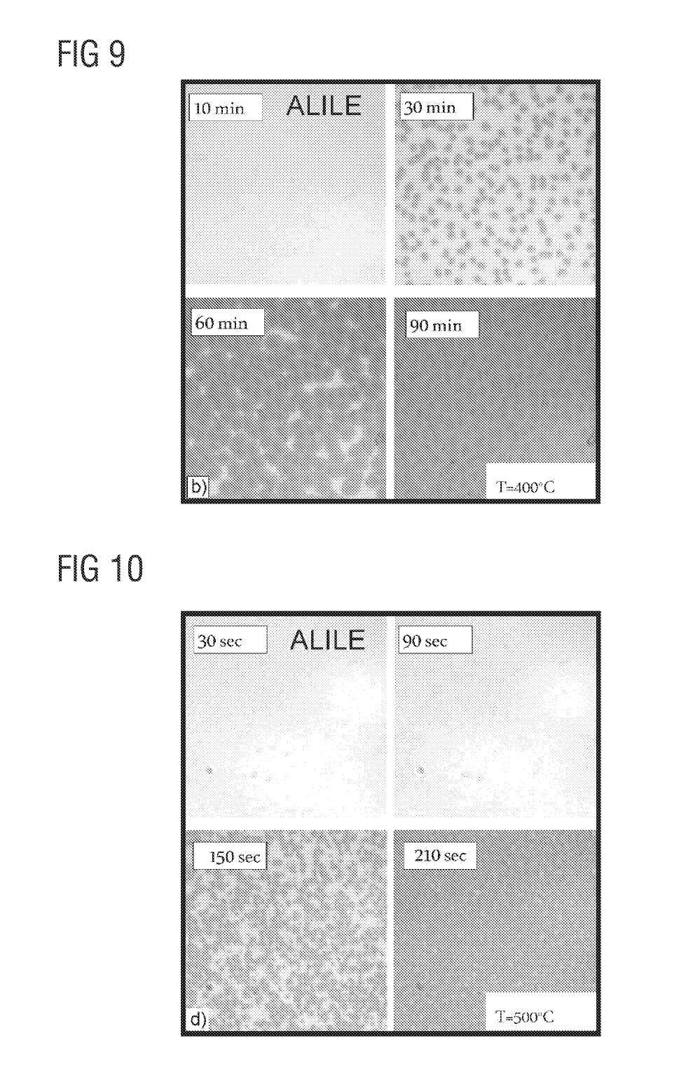

FIGS. 9 and 10 demonstrate the temporal evolution of a polycrystalline layer depending on the process temperature during a conventional aluminum induced layer exchange;

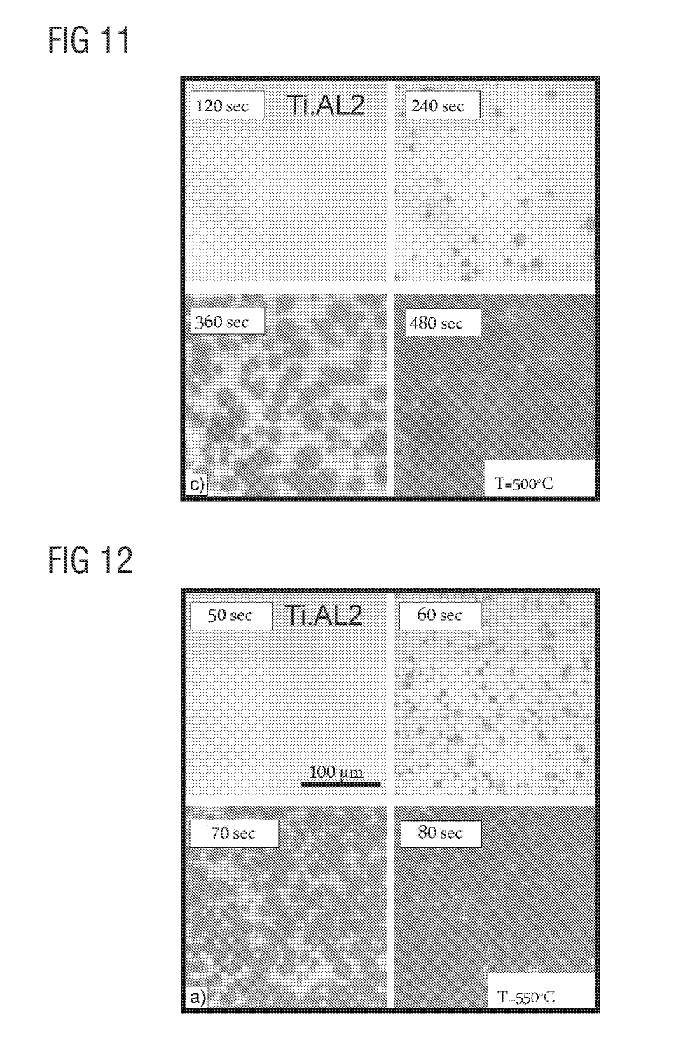

FIGS. 11 and 12 demonstrate the temporal evolution of a polycrystalline layer depending on process temperature in a aluminum induced layer exchange with an intermediate layer made form titanium;

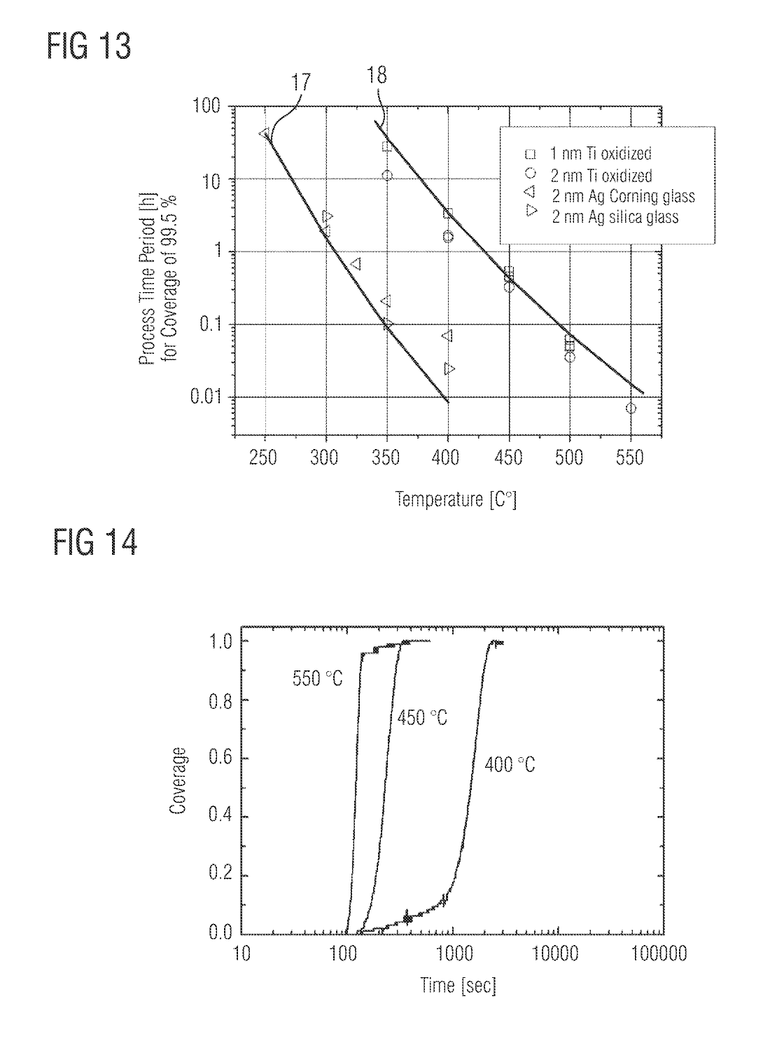

FIG. 13 illustrates the dependency of the process time on the process temperature for various processes;

FIG. 14 is a diagram, in which the coverage by polycrystalline material is plotted against the process time period of a metal induced crystallization process using aluminum oxide as a diffusion barrier;

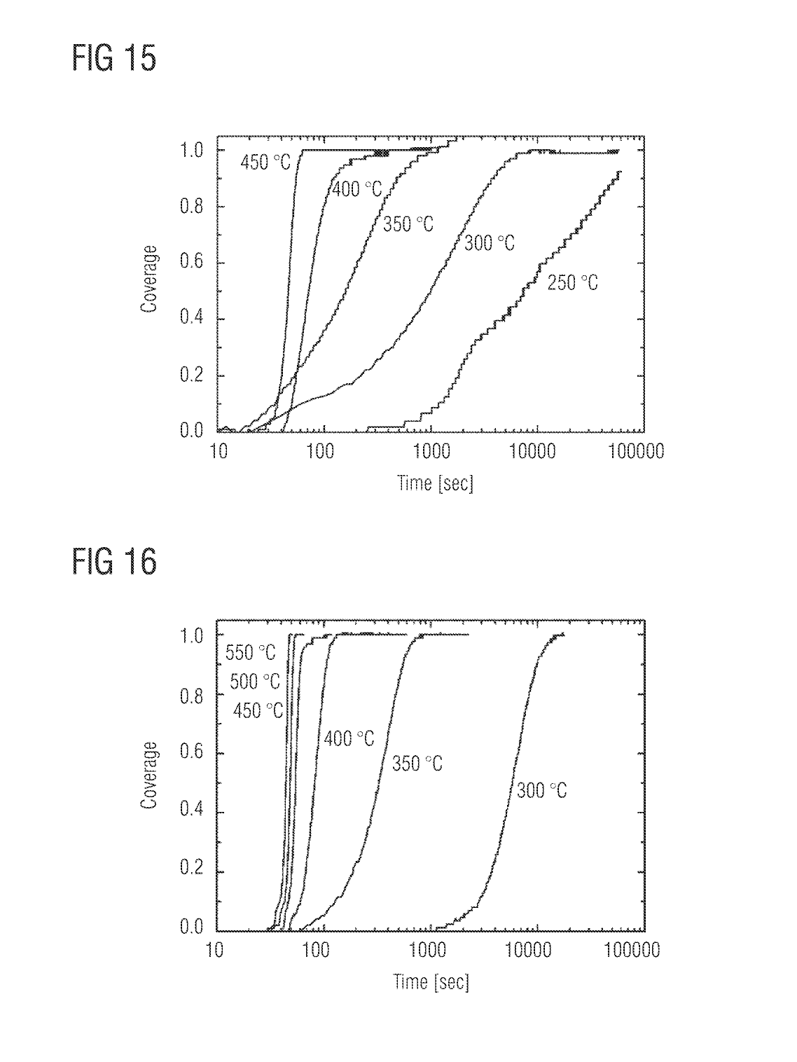

FIG. 15 is a diagram, in which the coverage by polycrystalline material is plotted against the process time period of a metal induced crystallization process using silver for the intermediate layer;

FIG. 16 is a diagram, in which the coverage by polycrystalline material is plotted against the process time period of a metal induced crystallization process having a titanium intermediate layer without oxidation; and

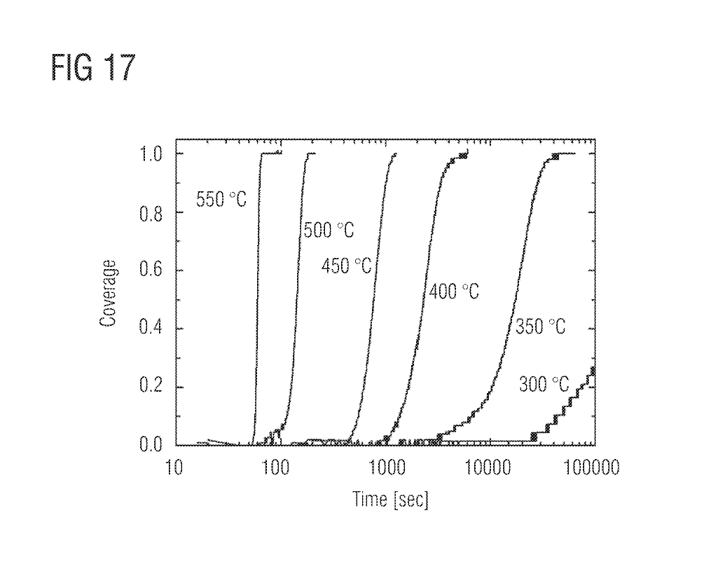

FIG. 17 is a diagram, in which the coverage by polycrystalline material is plotted against the process time period of a metal induced crystallization process having an oxidized titanium intermediate layer.

FIGS. 1 to 4 illustrate a metal induced crystallization process. For the process, a substrate 1 is used that may have an amorphous or crystalline structure. The substrate 1 may, for instance, be glass, silicon or a silicon wafer. On the substrate 1, a metallic activation layer 2 is deposited. The activation layer 2 is generally made from aluminum. The activation layer 2 has a thickness between 10 nm and 600 nm and has a typical thickness of about 200 nm. Instead of aluminum, silver or any other suitable material may also be used. The activation layer 2 is formed by using a thermal evaporation process, electron beam evaporation, sputtering or an electrochemical deposition process.

After finishing the deposition process, a thin intermediate layer 3 is formed on the activation layer 2. The intermediate layer 3 is produced on the basis of titanium and has a typical thickness between 1 nm to 10 nm.

On the surface of the intermediate layer 3, an amorphous initial layer 4 is formed. The amorphous initial layer 4 is composed of semiconductor material, for instance silicon and germanium. The amorphous initial layer 4 may be deposited by thermal evaporation, electron beam evaporation, sputtering or gas phase deposition. The thickness of the amorphous initial layer 4 should be comparable with the thickness of the activation layer 2. In most cases, the activation layer 2 should have a thickness between 0.6 and 0.8 of the amorphous initial layer 4. The probe comprising the substrate 1 and the sequence of layer deposited on the substrate 1 is then annealed with a process temperature below the eutectical temperature of the material system containing the components of the activation layer 2 and the amorphous initial layer 4. If silicon and/or germanium is used for the amorphous initial layer 4 and if aluminum or silver is used for the activation layer 2 the process temperature can be between 420° C. and 830° C. For instance, the eutectical temperature of the binary material system containing aluminum and germanium is around 420° C., the eutectical temperature of the binary material system containing silicon and aluminum is around 570° C. and the eutectical temperature of the binary system containing silicon and silver is around 830° C. During the annealing process a diffusion process 5 from the amorphous initial layer 4 into the activation layer 2 occurs.

As shown in FIG. 2, crystalline seeds of the material forming the amorphous initial layer 4 are forming in the activation layer 2 along the intermediate layer 3. The crystalline seeds 6 are growing into the activation layer 2 and become crystallites 7 whose vertical growth is finally limited by the surface of the substrate 1. The crystallites 7 may then further grow in lateral direction until a continuous polycrystalline final layer 8 is formed. The polycrystalline final layer 8 is covered with a mostly metallic final layer 9 as shown in FIG. 4. The outer amorphous final layer 9 generally comprises components of the original activation layer 2 and of the amorphous initial layer 4.

After the annealing process has been finished, the amorphous final layer 9 can be removed by a wet-chemical process, for instance by exposing the amorphous final layer 9 to hydrochloric acid. The intermediate layer 3 that is based on titanium can be removed by hydrofluoric acid. Finally, a polycrystalline silicon-germanium layer formed on the substrate 1 is obtained. The polycrystalline crystallites typically have a lateral extension up to 50 μm.

It should be noted that, after the deposition of the intermediate layer 3, the intermediate layer 3 may be exposed to air or to an oxygen atmosphere to provide the intermediate layer 3 with an oxide layer. This process step is not mandatory but improves the surface structure of the resulting polycrystalline final layer 8.

The time needed for forming the polycrystalline final layer 8 may vary between a few seconds and a few ten hours.

Using the intermediate layer 3 based on titanium increases the activation energy for the formation of new crystallites resulting in extended crystallites without slowing down the process if process temperatures are used for the annealing process that are comparable with temperatures of conventional methods.

A further advantage of using titanium for the intermediate layer 3 is the fact that the sequence of layers on the substrate 1 can also be inverted as shown in FIGS. 5 to 8. According to the inverted metal induced crystallization process an amorphous initial layer 10 is deposited on the substrate 1. Then the intermediate layer 3 is formed on the amorphous initial layer 10 and an outer metallic activation layer 11 is formed on the intermediate layer 3.

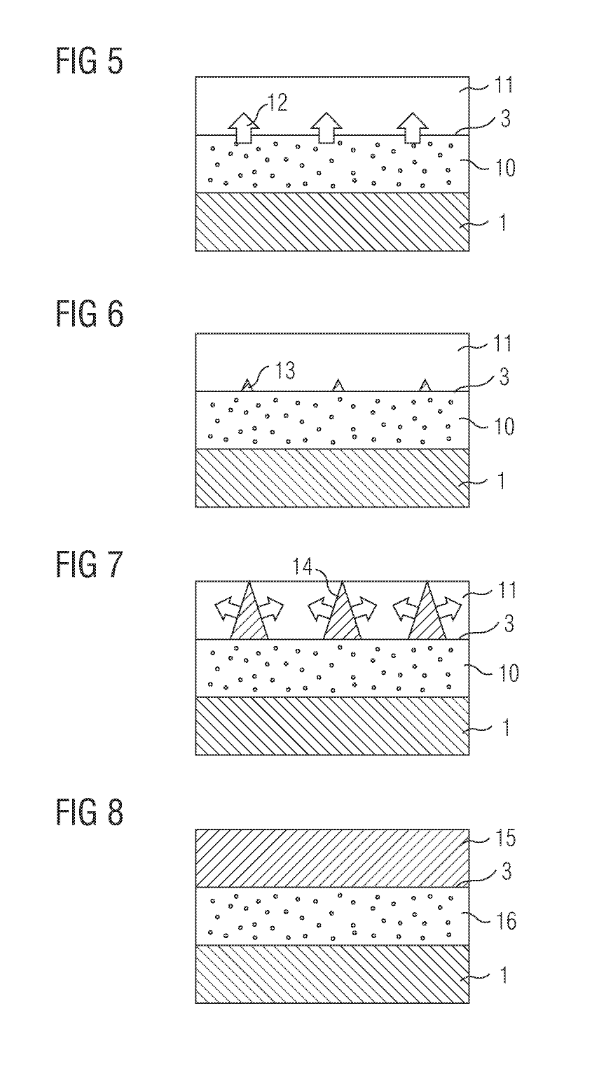

By annealing the probe formed by the substrate 1 and the sequence of layer formed on the substrate 1, a diffusion process 12 from the amorphous initial layer 10 into the activation layer 11 occurs resulting in seeds 13 that grow into the activation layer 11 along the intermediate layer 3. The seeds 13 shown in FIG. 6 further grow and become crystallites 14 as shown in FIG. 7.

Finally, the crystallites 14 form a continuous polycrystalline final layer 15 that is located above a metallic final layer 16 that is disposed between the polycrystalline layer 15 and the substrate 1 and that can be used as an electrical contact for contacting the polycrystalline layer 15. In particular, if the activation layer 11 is made from silver, the final metallic layer 16 provides a reflecting coating for the polycrystalline layer 15 so that radiation transmitted through the polycrystalline layer 15 can be reflected back into the polycrystalline layer 15.

After the amorphous initial layer 10 has been deposited, an oxide layer may form on the amorphous initial layer 10. Such a semiconductor oxide layer is generally an effective diffusion barrier, in particular if the semiconductor material is silicon. However, by producing the intermediate layer 3 from titanium, the oxide layer on the amorphous initial layer may be deoxidized since the electronegativity of titanium is lower than the electronegativity of silicon. For instance, the electronegativity of silicon is 1.9 on the Pauling scale whereas the electronegativity of titanium is 1.54. Thus, titanium will be able to deoxidize the oxide layer.

It should be noted that the electronegativity of silver is 1.93 on the Pauling scale. Therefore, the oxide layer on the amorphous initial layer 10 will not be deoxidized if the intermediate layer will be omitted and if the metallic activation layer 11 is formed directly on the amorphous initial layer. Experiments further showed that an intermediate layer 3 made from aluminum and a metallic activation layer 11 made from silver result in a lower quality of the polycrystalline layer 15 although the electronegativity of aluminum is around 1.61 on the Pauling scale and therefore also lower than the electronegativity of silicon.

In the following, a few further experimental results are shown for demonstrating the advantages associated with the use of an intermediate layer 3 based on titanium.

If the substrate 1 is transparent, the change of reflectivity of the layer that is located directly on the substrate 1 can be used as a measure for the progress of the transformation from the activation layer 2 into the polycrystalline final layer 8 since the material forming the activation layer 2 generally has another reflectivity than the material forming the polycrystalline final layer 8. In particular, if aluminum is used for the activation layer 2 and if the amorphous initial layer 4 is made from silicon the reflectivity is continuously decreasing and the appearance of the layer adjacent to the substrate 1 is darkening.

FIG. 9 demonstrates the change of reflectivity of a probe as seen through the glass substrate 1. FIG. 9 shows in particular a conventional aluminum induced layer exchange with an oxidized aluminum layer. The probe is annealed at a process temperature of 400° C. and after 90 minutes an advanced state of the polycrystalline final layer 8 is achieved.

However, the process can be accelerated by increasing the annealing temperature from 400° C. to 500° C. In this case, the formation of the polycrystalline final layer 8 reaches a state after 210 seconds which has not been reached yet after 10 minutes while annealing the probe at a temperature of 400° C., as can be recognized from FIG. 10.

FIGS. 11 and 12 show similar pictures of the layer adjacent to the substrate 1 for a process in which the oxide on the activation layer 2 is replaced by the intermediate layer 3 made from titanium.

FIG. 11 demonstrates the change of reflectance for an annealing temperature of 500° C. The comparison with FIG. 10 demonstrates that the conversion takes more time if titanium is used for forming the intermediate layer 3 if the same annealing temperature is used for both processes.

However, the annealing temperature can also be increased if titanium is used as an intermediate layer 3. FIG. 12 demonstrates that a considerable amount of polycrystallites is formed after 80 seconds if the probe is annealed at 550° C. Thus, the crystallization process can even considerably be accelerated by using titanium as intermediate layer 3.

FIG. 13 shows a diagram, in which a curve 17 illustrates the relation between the process time period and the process temperature for a metal induced crystallization process, in which silver is used for the intermediate layer 3. The process time period is the process time that is needed for achieving a coverage of 99.5% of the area. A further curve 18 illustrates the relation between the process time period and the process temperature of a metal induced crystallization in which titanium is used for the intermediate layer 3. A comparison of both curves 17 and 18 shows that an intermediate layer 3 made from titanium results in longer process time periods, if the same process temperature is used.

The process time period is described by the Arrhenius equation. The curves 17 and 18 are in particular described by t_{99.5}=exp((2*10⁺⁴/T[K])+B)[h] wherein B=−34.5 for curve 17 and B=−28.5 for curve 18. It should be noted that this relations hold for activation layer 2 or 11 with a thickness of 100 nm. If the thickness of the activation layer 2 or 11 is lower or higher than 100 nm, then the process time period scales linearly with the thickness of the activation layer 2 or 11.

FIGS. 14 to 17 show various diagrams in which the evolution of the coverage of the polycrystalline layer 8 is plotted against time.

FIG. 14 illustrates the evolution of the coverage of a conventional aluminum induced layer exchange process in which aluminum oxide is used as intermediate layer 3. The process time period various from 100 seconds at a process temperature of 500° C. to 1000 seconds at a process temperature of 400° C.

FIG. 15 illustrates the evolution of the coverage of the polycrystalline final layer 8 for temperatures between 250° C. and 450° C. for an aluminum induced layer exchange with a silver intermediate layer three. The process time period various from 50 seconds at a process temperature of 450° C. to roughly 3 hours at a temperature of 300° C.

FIG. 16 demonstrates the evolution of the coverage for a process in which titanium is used as intermediate layer 3 without any oxidation. The process time period varies from about 50 seconds at a process temperature of 550° C. to 6 hours at a temperature of 300° C.

If the titanium intermediate layer 3 is oxidized the process time period various between 60 seconds at a process temperature of 550° C. and more than 30 hours at a process temperature of 300° C.

However, it must be noted that the quality of the polycrystalline final layers 8 and 15 is considerably increased in comparison to metal induced crystallization processes in which aluminum oxide or a separate silver layer is used as diffusion barrier.

In addition, the use of a titanium process allows also an inverted metal induced crystallization process that can not reliably be performed by using silver as intermediate layer 3.

Although the process has been explained in detail with respect to an embodiment that uses titanium for the intermediate layer, the process can generally be performed with an intermediate layer comprising an oxidized transition metal wherein the oxidized transition metal may be confined within a separate partial layer formed alongside another partial unoxidized layer or wherein the intermediate layer may comprise an unlayered structure based on the oxidized transition metal.

Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds or groups described in conjunction with a particular aspect, embodiment or example of the invention are to be understood to be applicable to any other aspect, embodiment or example described herein unless incompatible therewith.

1-15. (canceled)

16. A method for producing polycrystalline layers comprising:
depositing a sequence of layers on a substrate (1) , the sequence of layers comprising an amorphous initial layer (4, 10), a metallic activation layer (2, 11) and an intermediate layer (3) disposed between the initial layer (4, 10) and the activation layer (2, 11); and
performing a heat treatment to form a polycrystalline final layer (8, 15) at the location of the activation layer (2, 11),
wherein the intermediate layer (3) is based on Ti.

17. The method according to claim 16, wherein the intermediate layer (3) comprises titanium oxide.

18. The method according to claim 16, wherein the intermediate layer (3) has a thickness between 1 nm and 10 nm.

19. The method according to claim 16, wherein the amorphous initial layer (4, 10) comprises at least one semiconductor material.

20. The method according to claim 16, wherein the amorphous initial layer (4, 10) comprises Si and/or Ge.

21. The method according to claim 16, wherein the amorphous initial layer (4, 10) has a thickness between 10 nm and 600 nm.

22. The method according to claim 16, wherein the activation layer (2, 11) is based on a transition metal.

23. The method according to claim 16, wherein the activation layer (2, 11) is based on Al, Sb or Ag.

24. The method according to claim 16, wherein the activation layer (2, 11) has a thickness between 10 and 600 nm.

25. The method according to claim 16, wherein the activation layer (2, 11) has a smaller thickness than the amorphous initial layer (4, 10).

26. The method according to claim 16, wherein the heat treatment is performed at a process temperature below a eutectic temperature of a material system comprising components of the amorphous initial layer (4, 10) and the activation layer (3) .

27. The method according to claim 26, wherein a duration of the heat treatment to form the polycrystalline final layer (8, 15) having a coverage of 99.5% of the layer area is longer than:
t[hr]=(Δx[nm]/100 nm)*exp((2*10⁺⁴/T[° K])−34.5),
wherein Δx is a thickness of the activation layer (2, 11) measured in nm and T is the process temperature of the heat treatment.

28. The method according to claim 16, wherein the activation layer (2) is deposited on the substrate (1), and wherein the polycrystalline final layer (8) is formed on the substrate (1).

29. The method according to claim 16, wherein the amorphous initial layer (10) is deposited on the substrate (1), and wherein the polycrystalline final layer (15) is formed on a metallic final layer (16) on the substrate (1).

30. A product for converting radiation into electrical energy, wherein the product is produced according to the method of claim 16.
